(19) United States
(12) Patent Application Publication
(10) Pub. No.: US 2025/0354290 A1
(43) Pub. Date: Nov. 20, 2025

(54) SYSTEMS AND METHODS FOR COOLING A CHUNK POLYCRYSTALLINE FEEDER

(71) Applicant: GlobalWafers Co., Ltd., Hsinchu (TW)

(72) Inventors: JaeWoo Ryu, Chesterfield, MO (US); SeongSu Park, Chungcheongnam-do (KR); JunHwan Ji, Chungcheongnam-do (KR); Carissima Marie Hudson, St. Charles, MO (US); William Lynn Luter, St. Charles, MO (US)

(21) Appl. No.: 18/666,359

(22) Filed: May 16, 2024

(51) Int. Cl. C30B 15/02; C30B 15/14; C30B 29/06

(52) U.S. Cl. CPC C30B 15/02; C30B 15/14; C30B 29/06

(57) ABSTRACT

A polycrystalline feed system for supplying chunk polycrystalline to a crucible containing a melt includes a feed tube having an outer sidewall and an outlet end and a heat exchanger extending around, and spaced from, the outer sidewall of the feed tube for cooling the feed tube. The feed system further includes a shield assembly connected to the feed tube. The shield assembly includes a heat shield extending radially between the outer sidewall of the feed tube and the heat exchanger to shield at least a portion of the feed tube from the heat of the melt.

### FIELD

The field generally relates to the production of silicon ingots, and more specifically, to systems and methods for cooling a chunk polycrystalline feeder of a crystal puller.

### BACKGROUND

Single crystal silicon productivity and crystal cost for a given crucible size and HZ configuration are improved by maximizing a charge size, reducing time of polycrystalline silicon meltdown and enabling multiple recharge capability. The initial meltdown process includes melting of a volume charge stack of polycrystalline within a crucible of the crystal puller and subsequent feeding of additional polycrystalline to the crucible as the initial volume charge stack of polycrystalline is expended.

Chunk or granular type polycrystalline silicon is commonly poured onto the molten silicon in the crucible via a quartz dumper system. Another known polycrystalline feeding method is to drop chunk type poly silicon above the silicon melt using a speed control feeding mechanism having a feed tube. In such a system, the feed tube is made of silicon and has a temperature-driven position limitation of the end of the tube over the melt. In some instances, due to the height of the end of the tube from the melt, silicon dust or crushed particles can be generated, which can negatively impact the crystal growth process. To reduce silicon dust or crushed particle generation, the tube has to be positioned at a closer distance from the surface of the melt. This however can cause damage or melting of the end of the tube. Silicon dust and particles can affect ZD success of crystal growth because they are the major source of LZD issue. Therefore, there is a need to reduce silicon dust or crushed particle generation during feeding of polycrystalline silicon.

This background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

In one aspect, a polycrystalline feed system for supplying chunk polycrystalline to a crucible containing a melt includes a feed tube having an outer sidewall and an outlet end and a heat exchanger extending around, and spaced from, the outer sidewall of the feed tube for cooling the feed tube. The feed system further includes a shield assembly connected to the feed tube. The shield assembly includes a heat shield extending radially between the outer sidewall of the feed tube and the heat exchanger to shield at least a portion of the feed tube from the heat of the melt.

In another aspect, an ingot puller for manufacturing a single crystal ingot includes a crucible for holding a crystal melt, a crystal puller housing that defines a growth chamber for pulling the ingot from the melt, the crucible being positioned within the growth chamber, and a polycrystalline feed system for supplying chunk polycrystalline to the crucible. The feed system includes a feed tube having an outer sidewall and an outlet end, a heat exchanger extending around, and spaced from, the outer sidewall of the feed tube for cooling the feed tube, and a shield assembly connected to the feed tube. The shield assembly includes a heat shield extending radially between the outer sidewall of the feed tube and the heat exchanger to shield at least a portion of the feed tube from the heat of the melt.

Various refinements exist of the features noted above in relation to the various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. Again, the brief summary presented above is intended only to familiarize the reader with certain aspects and contexts of the present disclosure without limitation to the claimed subject matter.

### BRIEF DESCRIPTION OF THE DRAWINGS

FIG. 1A is a section view of an ingot puller used to pull a crystal silicon ingot from a silicon melt.

FIG. 1B is a section view of an ingot puller and a feed system used to supply polycrystalline.

FIG. 2A is a section view of a feed tube and cooling jacket in accordance with an embodiment of the present disclosure.

FIG. 2B is a section view of a feed tube and cooling jacket in accordance with an embodiment of the present disclosure.

FIG. 3A is a section view of a polycrystalline feed system and cooling system for use with the ingot puller of FIGS. 1A and 1B in an extended feeding position.

FIG. 3B is a section view of a polycrystalline feed system and cooling system for use with the ingot puller of FIGS. 1A and 1B in a retracted position.

FIG. 4 is a section view of a bellows assembly of the cooling system of FIG. 3A.

FIG. 5 is a method of cooling an outlet end of a feed tube of a polycrystalline feed system.

FIG. 6 is a section view of an alternative feed system and cooling system for use with the ingot puller of FIGS. 1A and 1B in a retracted position.

FIG. 7 is a section view of the feed system and cooling system of FIG. 6 in an extended position.

FIG. 8 is an enlarged section view of a portion of the feed system and cooling system of FIG. 6 in the retracted position, in which the feed tube removed.

FIG. 9 is an enlarged section view of the portion of the feed system and cooling system of FIG. 8.

FIG. 10 is a section view of a heat shield of the feed system and cooling system of FIG. 6.

Like reference symbols in the various drawings indicate like elements.

### DETAILED DESCRIPTION

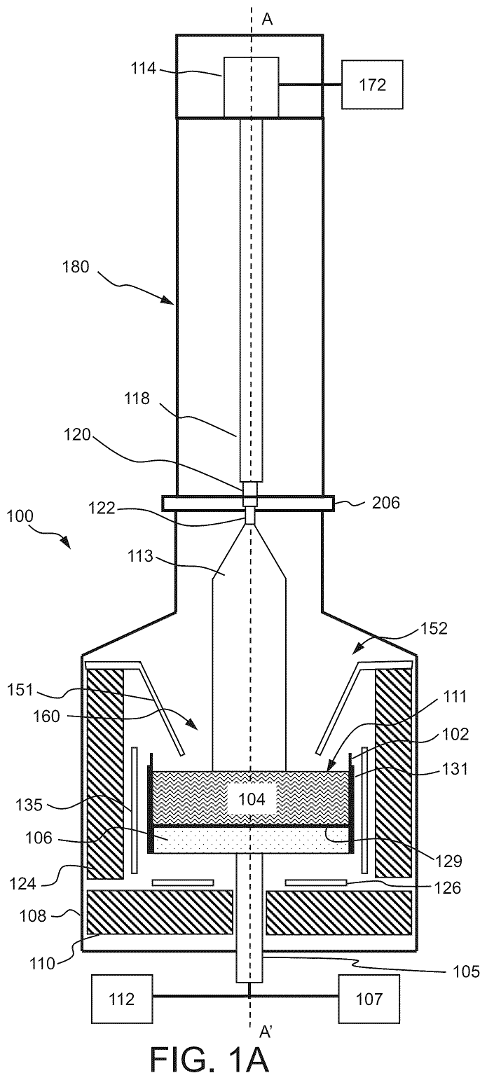

FIG. 1A is a section view of an ingot puller indicated generally at “100” used to pull or grow a crystal ingot from a silicon melt (the puller may be referred to as an ingot or crystal puller). The ingot puller 100 includes a crystal puller housing 108 that defines a growth chamber 152 for pulling an ingot 113 from a melt 104 of silicon. A controller 172 controls operation of the ingot puller 100 and its components. The ingot puller 100 includes a crucible 102 disposed within the growth chamber 152 for holding the melt 104 of molten material such as silicon. The crucible 102 is supported by a susceptor 106.

The crucible 102 includes a floor 129 and a sidewall 131 that extends upward from the floor 129. The sidewall 131 is generally vertical in this embodiment. The floor 129 includes the curved portion of the crucible 102 that extends below the sidewall 131. Within the crucible 102 is a silicon melt 104 having a melt surface 111 (i.e., melt-ingot interface). The susceptor 106 is supported by a shaft 105. The susceptor 106, crucible 102, shaft 105 and ingot 113 have a common longitudinal axis A or “pull axis” A.

A pull chamber 180 is connected to growth chamber 152 to start crystal growth. The pull chamber 180 includes a pulling mechanism 114 for growing and pulling an ingot 113 from the melt 104. Pulling mechanism 114 includes a pulling cable 118, a seed holder or chuck 120 coupled to one end of the pulling cable 118, and a seed crystal 122 attached to the seed holder or chuck 120 for initiating crystal growth. One end of the pulling cable 118 is connected to a pulley (not shown) or a drum (not shown) within the pulling mechanism 114, or any other suitable type of lifting mechanism, for example, a shaft, and the other end is connected to the seed holder or chuck 120 that holds the seed crystal 122. In operation, the seed crystal 122 is lowered to contact the melt 104. The pulling mechanism 114 is operated by a controller to cause the seed crystal 122 to rise. This causes a crystal ingot 113 to be pulled from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. As the ingot grows, the melt 104 is consumed and the height of the melt in the crucible 102 decreases. The crucible 102 and susceptor 106 may be raised to maintain the melt surface 111 at or near the same position relative to the ingot puller 100.

The ingot puller 100 may include an inert gas system to introduce and withdraw an inert gas such as argon from the growth chamber 152. The ingot puller 100 may also include a dopant feed system (not shown) for introducing dopant into the melt 104.

The ingot puller 100 includes bottom insulation 110 and side insulation 124 to retain heat in the puller apparatus 100. In the illustrated embodiment, the ingot puller 100 includes a bottom heater 126 disposed below the crucible floor 129 and a heater 135 and a susceptor 106 that encircles the crucible 102 to maintain the temperature of the melt 104 during crystal growth. The heater 135 is disposed radially outward to the crucible sidewall 131 as the crucible 102 travels up and down the pull axis A. The heater 135 and bottom heater 126 may be any type of heater that allows the heater 135 and bottom heater 126 to operate as described herein. The heaters 135, 126 are suitably resistance heaters. The side heater 135 and bottom heater 126 may be controlled by a control system (not shown) so that the temperature of the melt 104 is controlled within a predetermined range throughout the pulling process.

The ingot puller 100 may also include a reflector 151 (or “heat shield”) disposed within the growth chamber 152 and above the melt 104 which shrouds the ingot 113 during ingot growth. The reflector 151 may be partially disposed within the crucible 102 during crystal growth. The reflector 151 defines a central passage 160 for receiving the ingot 113 as the ingot is pulled by the pulling mechanism 114. The reflector 151 may be a heat shield adapted to retain heat underneath itself and above the melt 104. Other reflector designs and materials of construction (e.g., graphite) may be used without limitation.

According to the Czochralski crystal growth process, a quantity of polycrystalline silicon, or polycrystalline, is charged to the crucible 102 (e.g., charge of 250 kg or more). A variety of sources of polycrystalline silicon may be used including, for example, granular polycrystalline silicon produced by thermal decomposition of silane or a halosilane in a fluidized bed reactor or polycrystalline silicon produced in a Siemens reactor. Once polycrystalline silicon is added to the crucible 102 to form a charge, the charge is heated to a temperature above about the melting temperature of silicon (e.g., about 1412° C.) to melt the charge. In some embodiments, the charge (i.e., the resulting melt) is heated to a temperature of at least about 1425° C., at least about 1450° C. or even at least about 1500° C.

With reference to FIGS. 1B, 2A, 3A and 3B, a polycrystalline feed system 200 introduces a solid-phase polycrystalline charge 202 (referred to as “polycrystalline 202”) through a feed tube 270 and into the crucible 102. As (a full or part of) the initial charge of polycrystalline silicon melts, additional polycrystalline silicon is fed by the polycrystalline feed system 200. As shown in FIG. 1B, the feed tube 270 may be positioned such that polycrystalline is added to the melt 104 within the crucible 102.

The feed tube can be made from a material selected from the group consisting of quartz, silicon, metal oxide, silicon oxide, and suitable metals appropriately cooled or protected such as by coating to prevent contaminating the process, or a combination of these materials.

The polycrystalline 202 that is fed to the crucible 102 by the polycrystalline feed system 200 may be, for example, granular, chunk, chip, or a combination of thereof, and is typically silicon but can include other materials. Chunk polycrystalline typically has a size of between 3 and 45 millimeters (e.g., the largest dimension), and granular polycrystalline typically has a size between 400 and 1400 microns.

The polycrystalline feed system 200 includes at least a hopper 205 and the feed tube 270. Hopper 205 stores the polycrystalline 202 and the hopper 205 feeds the polycrystalline 202 into the feed tube 270 by a gravity feed or vibration system, or other system capable of feeding at a metered feed rate appropriate for the process such as a rotating tube with a helix feature on the interior wall to convey material. In some embodiments, the polycrystalline feed system further includes an interchangeable tray (not shown) and a vibrator (not shown) which vibrates the interchangeable tray such that the polycrystalline 202 from the hopper falls into the feed tube 270. The feed tube 270 receives polycrystalline that exits interchangeable tray due to vibration caused by vibrator. Example components of the polycrystalline feed system 200 are shown and described in U.S. Pat. No. 10,577,717, which is incorporated herein by reference for all relevant and consistent purposes.

The polycrystalline feed system 200 is enclosed within a feed housing 204 and the feed housing 204 is separated from the crystal puller housing 108 by a valve mechanism 206. The valve mechanism 206 may be used to seal the feed tube 270 during periods in which silicon is not being added to the feed tube 270. Both the feed housing 204 and the crystal puller housing 108 are under vacuum conditions. In some embodiments, both the feed housing 204 and the crystal puller housing 108 have a pressure in the range of 10-15 torr.

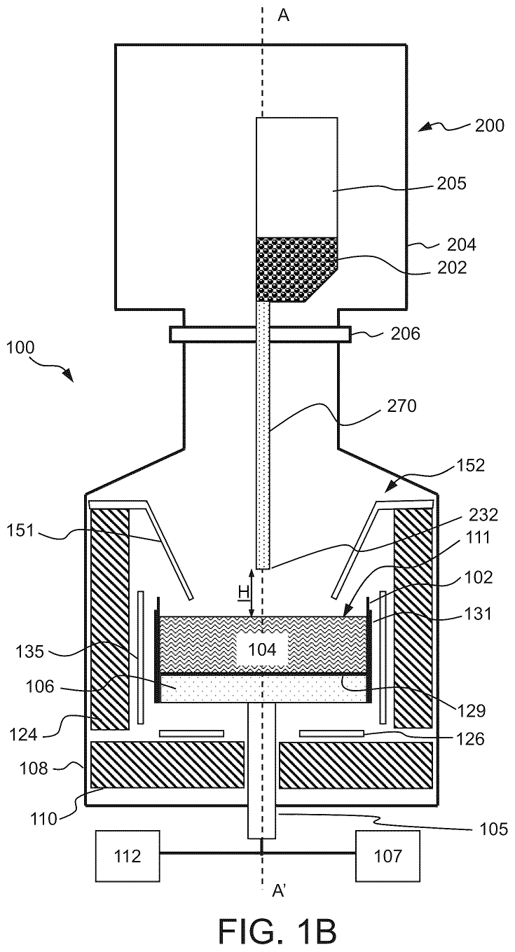

Before adding solid silicon to the initial melt 104, the polycrystalline feed system 200 is docked within the feed housing 204 and the feed tube 270 feed tube 270 is lowered into the growth chamber 152 (e.g., by use of motorized gear system). Silicon is introduced into the feed tube 270 by the polycrystalline feed system 200. Solid silicon passes through the feed tube 270 and is discharged through an outlet 272 (as best shown in FIG. 2) of the feed tube 270. Discharged solid silicon collects on the melt surface 111 and subsequently liquifies into the melt 104. Once the melt 104 is fully formed or replenished, the feed tube 270 is removed from the growth chamber 152.

Referring now to FIGS. 2A and 2B, the feed tube 270 includes an inlet 274 (which may be engaged with a feed tray disposed above the feed tube 270) and an outlet 272. The feed tube 270 includes a conduit 276 through which the polycrystalline 202 travels. The feed tube 270 may include a kick plate 278 disposed below the conduit portion 276 that directs the polycrystalline 202 into the crucible 102.

The conduit 276 of the feed tube 270 may include baffles (not shown) to control the speed of the polycrystalline 202 through the feed tube 270. The silicon feed tube 270, and its components (e.g., kick plate 278, conduit portion 276, guide section 166, and/or tube section 178) are suitably made of silicon or graphite.

As shown in FIG. 1B, the outlet 272 is positioned a height H from the melt surface 111 prior to introducing polycrystalline 202 to the melt 104. The outlet 272 is disposed or positioned close to the melt surface 111 to avoid silicon dust or crushed particles generation as the polycrystalline 202 travels through the conduit portion 276 of the feed tube 270. However, because the temperature at the melt surface 111 is in the range of about 1400° C. to at least 1500° C. or higher, the feed tube 270 (and in particular the outlet 272 and conduit portion 276) is prone to thermal damage as the outlet 272 approaches the melt surface 111. Thermal damage includes, but is not limited to, melting and cracking. The height H is thus defined by the distance from the outlet 272 to the melt surface 111 when the feed tube 270 is depositing polycrystalline 202. For the illustrated embodiment, the outlet 272 can extend to the reflector 151, or the height H is approximately 170 mm.

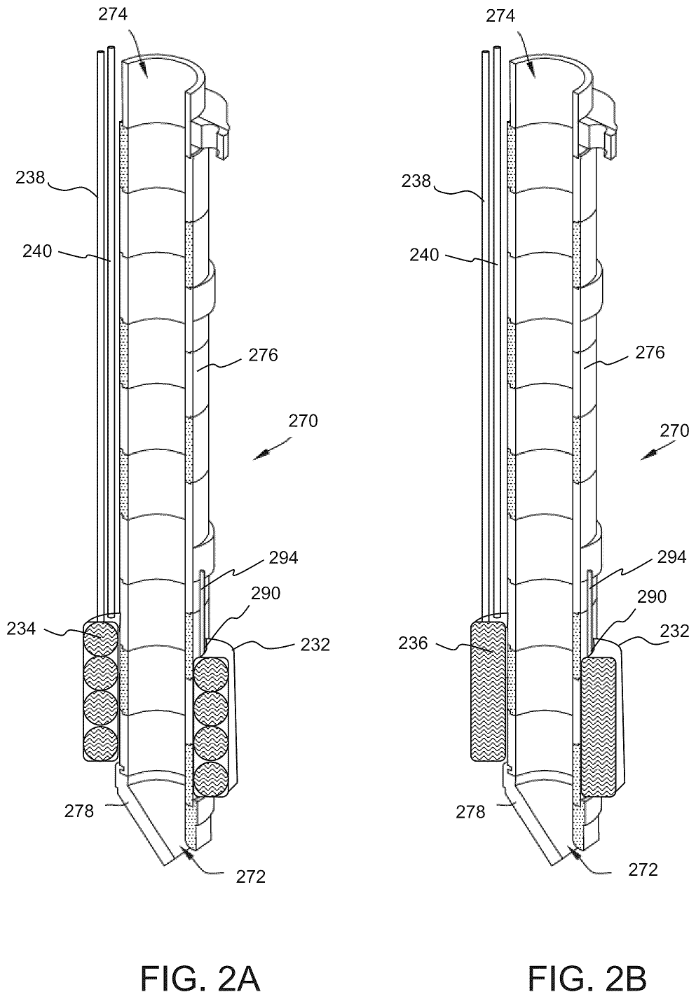

As shown in FIGS. 2A, 2B, 3A and 3B, a cooling system 230 can be attached to the polycrystalline feed system 200 for reducing the temperature of the outlet 272 of the feed tube 270 when the feed tube 270 is depositing polycrystalline 202. The cooling system 230 protects the outlet 272 of the feed tube 270 from the extreme heat in the growth chamber 152. As explained in detail below, the cooling system 230 allows for the outlet 272 of the feed tube 270 to be positioned closer to the melt surface 111 relative to the height H of the outlet 272 without the cooling system 230.

As best shown in FIGS. 3A and 3B, the cooling system 230 includes a fluid source 239 positioned outside from the feed housing 204 and a heat exchanger 232 positioned at or near the outlet 272 of the feed tube 270 such that the heat exchanger 232 fully surrounds the outlet 272, or more specifically, the heat exchanger 232 extends circumferentially around a portion of the feed tube 270 that is at or near the outlet 272. The heat exchanger 232 is suitably positioned near regions that are most susceptible to extreme thermal temperatures due to proximity to the melt surface 111.

The heat exchanger 232 is fluidly connected to the fluid source 239 by a fluid inlet conduit 238 and a fluid outlet conduit 240 defining a cooling circuit as shown in FIGS. 2A and 2B. As shown in FIGS. 3A and 3B, the fluid circuit includes a valve or pump 237 connected to a processor for controlling the flow of fluid. The fluid is a temperature-controlling fluid or coolant and is in thermal communication with the cooling system 230. In the example embodiment, fluid conduits 212 receive fresh fluid from the fluid source 239. The flow rate is maintained generally constant by the pump 237.

The fluid source 239 is suitably a reservoir (not shown) that has a sufficient volume such that the fluid circulated through the reservoir is uniformly cooled. Alternatively, fluid can be partially expelled from the reservoir and fresh fluid can be added to the reservoir. The fluid may be chilled plant water of a relatively constant temperature (e.g., between about 24° C.+/−1° C. and about 35° C.+/−1° C.) that is obtained from the fluid source 239 or other source before entering the cooling system 230. After contact with the heat exchanger 232, the fluid is returned to the fluid source 239 or reservoir.

As shown in FIGS. 2A and 2B, the heat exchanger 232 contacts an outer surface 290 of the feed tube 270 such that the heat exchanger 232 extracts heat from the outer surface of the outlet 272 of the feed tube 270. The heat exchanger 232 can be selected from the group consisting of a cooling jacket, a coiled conduit and a reservoir. Fluid passes through the heat exchanger 232 to promote the transfer of heat from the outer surface 290 of the feed tube 270 to the heat exchanger 232.

As shown in FIG. 2A, the exchanger 232 includes a plurality of coiled tubes 234, and/or a single tube having a plurality of coiled sections, surrounding the outer surface 290 of the feed tube 270 and in contact with the outer surface 290. As shown in FIG. 2B, the heat exchanger 232 is a cooling jacket including a reservoir 236 through which liquid flows through. The heat exchanger 260 can further include a radiation shield (not shown) surrounding the heat exchanger 260. The radiation shield can be a refractory metal such as molybdenum, tantalum, or tungsten. Furthermore, multiple radiation shields can be included to impede the radiant heat flux from the molten silicon.

As shown in FIGS. 3A and 3B, in operation, the fluid source 239 circulates fluid through the heat exchanger 232 as the feed tube 270 is lowered into the growth chamber 152 (of FIG. 1). As shown in FIG. 3A, the outlet 272 of the feed tube 270 is lowered to a height H1 from the surface melt 111. Because the heat exchanger 232 extracts heat from the outlet 272 of the feed tube 270, the height H1 is less than the height H (as shown in FIG. 1, where the heat exchanger 232 is not included). For the illustrated embodiment, the outlet 272 can extend below the reflector 151 of FIG. 1. Depending on the ingot puller configuration, the height H1 can be in the range of 50 mm to 150 mm less than the height H (as shown in FIG. 1), where the heat exchanger 232 is not included. In other configurations, the height H1 is in the range of 50 mm to 250 mm less than the height H.

The height H1 of the outlet 272 from the surface melt 111 can also be increased or decreased by movement of the shaft 105 and susceptor 106 along the longitudinal axis A. As the melt 104 is depleted and additional polycrystalline 202 is fed into the crucible 102, an island of unmelted polycrystalline temporarily forms on the melt surface 111. The polycrystalline island prevents splashing during feeding, which also protects the outlet 272 from splash damage. This increases the lifetime of the feed tube 270, especially when the outlet 272 is closer to the melt due to the benefit of the heat exchanger 232.

Because the fluid source 239 is external to the feed housing 204, bellows assembly 250 is secured to the feed housing 204 such that a vacuum or low pressure state is maintained within the feed housing 204. The bellows assembly 250 retracts and extends as the feed tube 270 is lowered into the growth chamber 152 (of FIG. 1). As shown in FIG. 3B, the bellows assembly 250 extends by the difference between height H1 and a height H2, where the height H2 is the distance from the outlet 272 when the feed tube 270 is retracted.

The heat exchanger 232 may also be retrofitted onto existing feed systems. By way of example, the heat exchanger 232 can be affixed onto the outer surface 290 of a feed tube and connected to an external reservoir and valve, or pump. As shown in FIGS. 2A and 2B, the outer surface 290 can include stainless steel bars 294 as an attachment fixture to which the heat exchanger 232 can be attached to. The stainless-steel bars 294 can have bracket to hold heat exchanger 232. After the heat exchanger 232 is affixed to the stainless steel bars 294, fluid conduits (238, 240) are connected to heat exchanger 232.

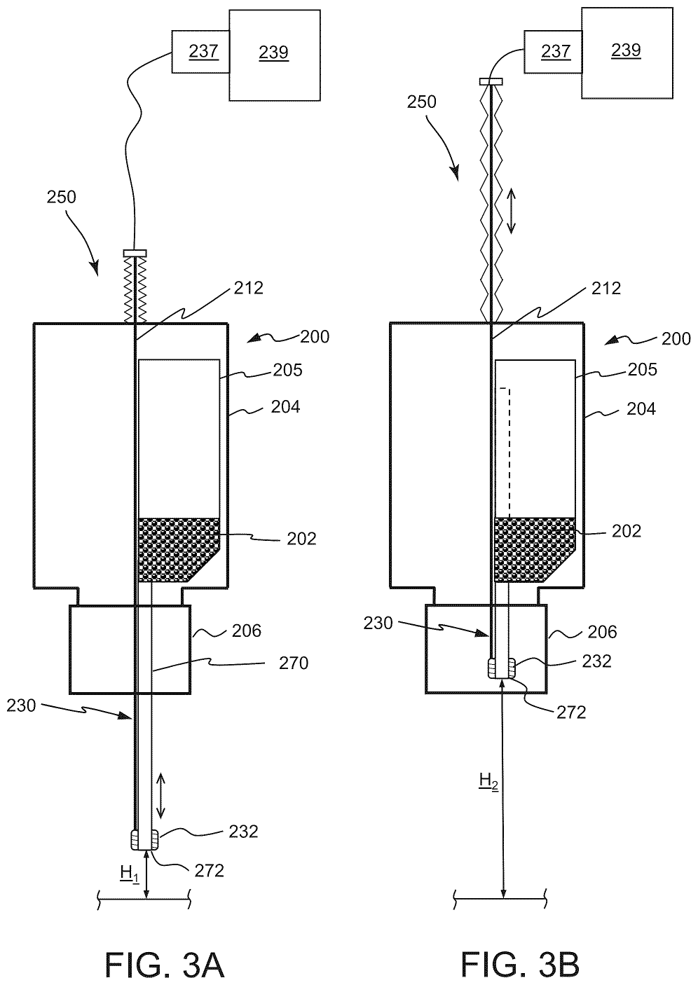

As shown in FIG. 4, the bellows assembly 250 comprises multiple bellows sections 252 connected in series. Each bellows section 252 includes a top plate 254 and a bottom plate 256. In some embodiments, the top-most bellows sections 252 are bolted together. In some embodiments, the bellows assembly 250 further comprises a support rail 258 for translating the bellows assembly 250 between extensions and compressions.

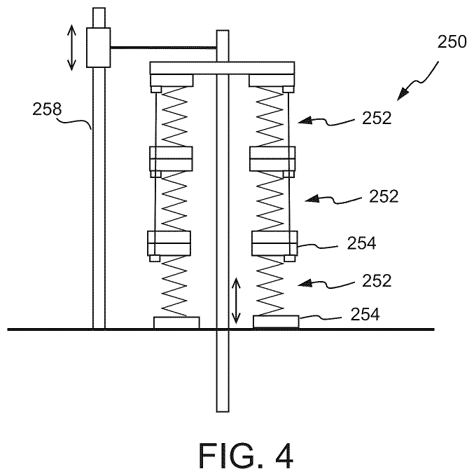

A method 400 for cooling an outlet end of a feed tube of a polycrystalline feed system is illustrated in FIG. 5. The method 400 includes supplying 402 a coolant to a cooling jacket, lowering 404 the feed tube to a first distance from a top surface of the melt; and supplying 406 chunk polycrystalline to the melt.

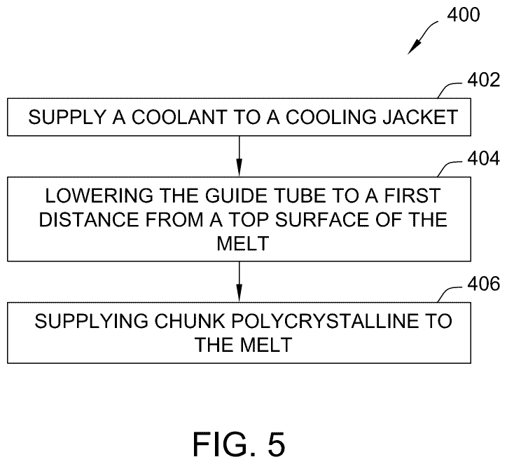

FIG. 6 shows an alternative embodiment of a feed system 600 and cooling system 630 for use with the ingot puller 100 of FIG. 1. The feed system 600 and cooling system 630 are similar to the feed system 200 and cooling system 230, shown in FIGS. 2A-4 except that, in the example embodiment, the heat exchanger 602 is not positioned on the feed tube 270 but is instead stationary (i.e., in-situ) within the growth chamber 152 (shown in FIG. 1A).

Referring to FIG. 6, the feed system 600 includes the heat exchanger 602 and a feeder connection flange 604. The heat exchanger 602 and the feeder connection flange 604 are connected to the housing 108 and are fixed in position within the growth chamber 152 (shown in FIG. 1A). The heat exchanger 602 is positioned below the feeder connection flange 604 and at least partially within the central passage 160 of the reflector 151. The feeder connection flange 604 and the heat exchanger 602 each extend annularly around the feed tube 270. The heat exchanger 602 is fixed in position within the growth chamber 152 and is supported above the crucible 102 (shown in FIG. 1A) by connection with the housing 108. Specifically, the heat exchanger 602 is supported by a furnace tank flange (not shown) that is positioned within the housing 108. In other embodiments, the heat exchanger 602 is attached to the feeder connection flange 604 and supported above the crucible 102 (shown in FIG. 1A) by the feeder connection flange 604. In the example, the heat exchanger 602 is a cooling jacket. In some embodiments, the cooling jacket may be a passive (i.e., non-fluid based cooling jacket). In other embodiments, the cooling jacket circulates a cooling fluid within a body of the cooling jacket and to a fluid source, similar to fluid source 239 shown in FIGS. 3A and 3B. In other embodiments any other suitable heat exchangers may be used.

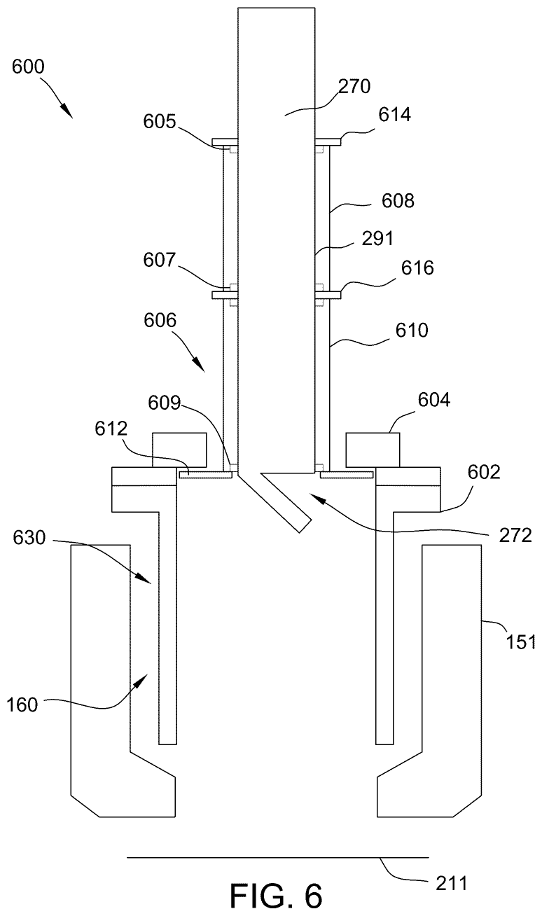

The feed system 600 further includes a shield assembly 606 that includes a first tube support 608, a second tube support 610, and a heat shield 612 connected to the tube supports 608, 610. The first tube support 608 and second tube support 610 are connected to the feed tube 270 by a first support ring 614 and a second support ring 616, respectively. The first support ring 614 and the second support ring 616 are each attached to the feed tube 270 (e.g., by welding) such that the shield assembly 606 moves together with the feed tube 270 as the feed tube 270 is extended or retracted. The heat shield 612 is attached to the second tube support 610 and is positioned at the outlet 272 of the feed tube 270. The heat shield 612 extends fully around the feed tube 270 and shields the feed tube 270 from heat from the melt when the feed tube 270 is extended, as shown in FIG. 7.

Referring to FIG. 6, the first support ring 614 and second support ring 616 each extend annularly around the feed tube 270 and are substantially identical. The feed tube includes a plurality of ledges 605, 607, 609 extending radially outward from the outer sidewall 291 of the feed tube 270 and circumferentially around the feed tube 270. The first support ring 614 is seated on a first ledge 605 and the second support ring 616 is positioned between a pair of second ledges 607. The heat shield 612 is positioned below and in contact with a third ledge 609.

The first tube support 608 includes one or more cables (alternatively “hangers”), with each cable being tightened and fastened to a respective one of the first support ring 614, the second support ring 616, and the heat shield 612. Cables of the first tube support 608 are each attached to the first support ring 614 and the second support ring 616. Cables of the second tube support 610 are each attached to the second support ring 616 and the heat shield 612. The cables of the first tube support 610 and the second tube support 612 are under tension to apply a compressive force on the feed tube 270 by engagement of the support rings 614, 616, and the heat shield 612 with the respective ledges 605, 607, 609. The compressive force holds segments of the feed tube 270 in place and the tube supports 608, 610 carry the load of the feed tube 270 during operation. In the example, the first tube support 608 and the second tube support each include six cables (i.e., twelve cables in total) circumferentially spaced around the feed tube 270. The cables include a material having a high material strength when exposed to high temperatures, such as tungsten.

In other embodiments, the feed tube 270 may include any number of ledges 605, 607, 609 or projecting features that enable engagement between the support rings 614, 616 and heat shield 612 and the feed tube 270 as described. For example, in one embodiment, the first ledge 605 and the third ledge 609 include a pair of ledges, similar to the second ledge 607 in FIG. 6. In another embodiment, the feed tube 270 may include one or more notches (not shown) that receive a portion of the support rings 614, 616, and/or heat shield 612 therein. In another embodiment, the first tube support 608 and second tube support 610 includes one or more rods (not shown) in addition or as an alternative to the cables.

In other embodiments, the feed tube 270 may include any number of support rings and tube supports. For example, in one embodiment, the shield assembly 606 does not include one of the first support ring 614 and the second support ring 616 and instead the tube support extends from the single support ring to the heat shield 612. In other embodiments, one of first support ring 614 and second support ring 616 may be attached to a different structure of the feed tube 270 apart from feed tube 270. For example, in one embodiment, the feed tube 270 includes an annular housing (not shown) that extends around an upper portion of feed tube 270. In some such embodiments, the first support ring 614 is attached to the annular housing and the second support ring 616 is attached to the feed tube 270.

Referring to FIG. 7, the feed tube 270 and shield assembly 606 are shown in the extended position, with the outlet 272 of the feed tube 270, and particularly the kick plate 278, positioned adjacent to the melt surface 211. The heat exchanger 602 is sized such that the heat exchanger 602 overlaps the heat shield 612 when the feed tube 270 is both extended and retracted. That is, when extended, the heat shield 612 does not extend longitudinally beyond the heat exchanger 602. As a result, the heat shield 612 provides a thermal shadow to portions of the feed tube 270 and heat exchanger 602 that are upstream of (i.e., above) the heat shield 612.

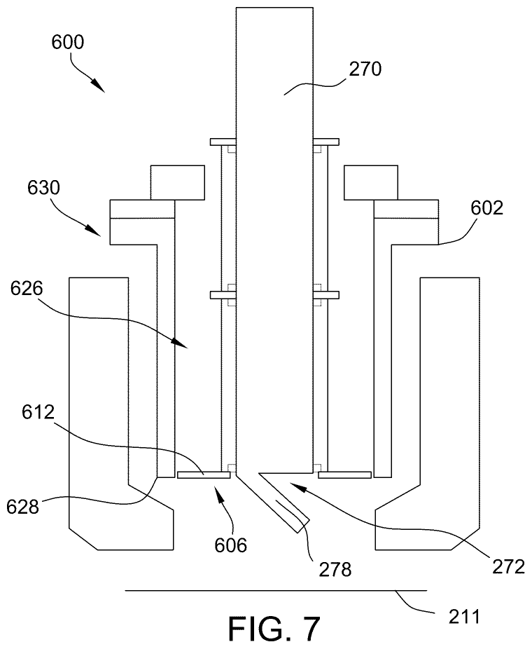

FIG. 8 shows an enlarged view of the feed system 600 with the feed tube 270 removed. As shown in FIG. 8, the feeder connection flange 604 includes a lower wall 618 connected to the heat exchanger 602 and an upper wall 620 positioned above the lower wall 618 and extending radially inward from the lower wall 618. The upper wall 620 and lower wall 618 collectively define a notch 622 therein. When the feed tube 270 (shown in FIG. 6) is retracted, the heat shield 612 is positioned within the notch 622. The lower wall 618 and the heat exchanger 602 are positioned in alignment to define a substantially continuous inner surface 624 defining a heat exchange chamber 626 that extends longitudinally from the upper wall 620 to a distal end 628 (shown in FIG. 7) of the heat exchanger 602.

The heat shield 612 includes a radially outer surface 631, a radially inner surface 632, a top surface 634, and a bottom surface 636. The inner surface 632 defines an annular conduit opening 638 that is sized to receive the feed tube 270 (shown in FIG. 7). Specifically, the conduit opening 638 has a diameter, indicated at D1, that is greater than a diameter of the feed tube 270, such that the feed tube 270 is received within the opening 638 and the heat shield 612 does not contact the outer sidewall 291 (shown in FIG. 6) of the feed tube 270. That is, the heat shield only contacts the ledge 609 (shown in FIG. 6) on the feed tube 270. In other embodiments, the heat shield 612 is sized to contact the outer sidewall 291 of the feed tube 270. In further embodiments, the inner surface 632 of the heat shield 612 and/or a seal (not shown) may contact at least a portion of the feed tube 270.

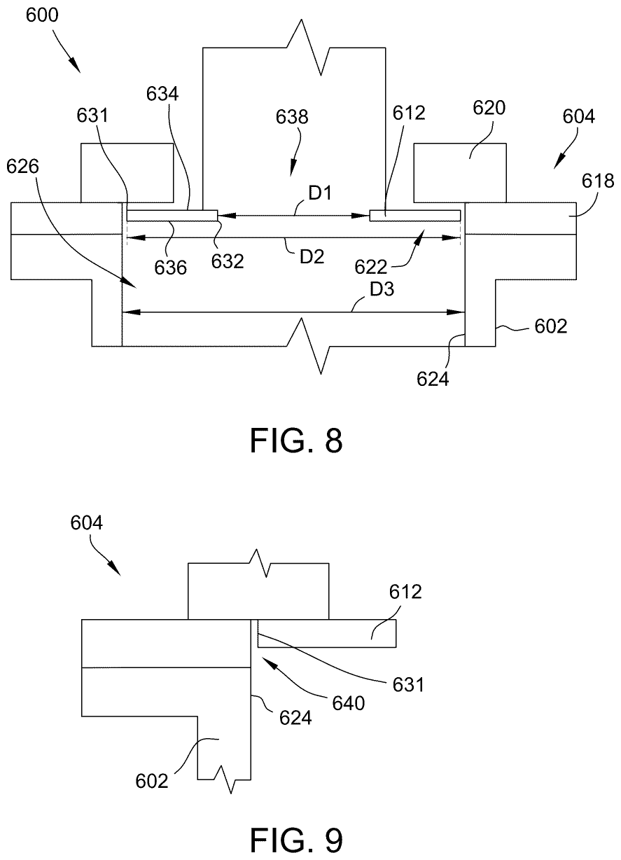

The radial outer surface 631 of the heat shield 612 defines a diameter of the heat shield 612, indicated at D2. The heat shield 612 is sized such that the diameter D2 is close to, but less than the diameter D3 of the heat exchange chamber 626. A radial gap 640 is defined between the heat shield 612 and the inner surface 624, as shown in FIG. 9. The radial gap 640 extends around a circumference of the heat shield 612 such that the heat shield 612 may be moved longitudinally within the heat exchange chamber 626 without being obstructed by the heat exchanger 602 or the feeder connection flange 604. The heat shield 612 is sized such that the radial gap 640 is large enough to enable the longitudinal movement of the heat shield 612 within the heat exchange chamber 626, while limiting heat convection through the radial gap 640. When in the extended position, as shown in FIG. 7, the heat shield 612 does not contact the feed tube 270 or the heat exchanger 602.

In some embodiments, the diameter D2 of the heat shield 612 may be substantially the same as the diameter D3 of the heat exchange chamber 626 such that the outer surface 631 of the heat shield 612 contacts the inner surface 624 of the heat exchange chamber 626. In some embodiments, the heat shield 612 and/or the heat exchanger 602 may include one or more guide features (not shown), such as a projection, a track, a roller, etc. to guide movement of the heat shield 612 along the inner surface 624 of the heat exchanger 602.

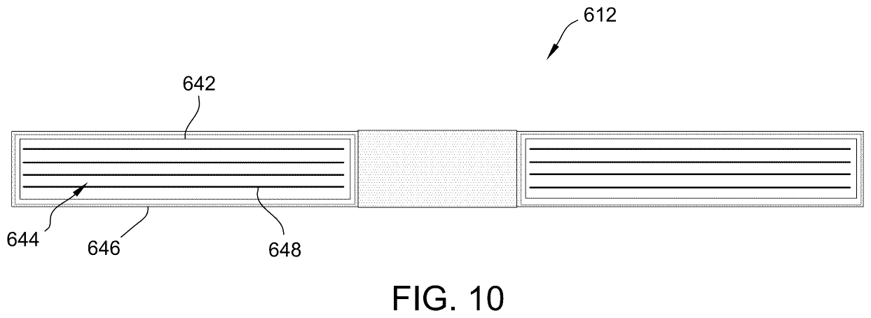

FIG. 10 shows an enlarged view of the heat shield 612 shown in FIGS. 6-9. The heat shield 612 includes an annular outer shell 642 defining an interior cavity 644. The heat shield 612 includes a heat resistant coating 646 applied on all exterior surfaces of the outer shell 642. In the example, the coating 646 includes silicon carbonate, though other coatings may be used. The heat shield 612 includes a plurality of shielding layers 648 positioned in a stacked arrangement within the interior cavity 644. In the example, the heat shield 612 includes four stacked shielding layers 648 of Molybdenum sheet, though any number of layers and/or suitable heat shielding material may be used.

The examples disclosed above enable the feed tube to be positioned closer to the surface of the melt within the crystal puller (as compared to the prior art), thereby reducing the impact of silicon dust or crushed particle generation. The outlet of the feed tube is less prone to thermal damage. The embodiments also enable cooling an outlet of the feed tube, for example by a heat exchanger abutting the outlet. By cooling the outlet, the feed tube can be placed closer to a surface melt, thereby also reducing dust and particle generation. Positioning the outlet of the feed tube closer to the surface of the melt makes the outlet more prone to splash from the melt, however because an island of unmelted polycrystalline is formed on the surface of the melt during feeding, splash damage is minimized. This allows for the crucible to be moved closer to the outlet of the feed tube, further reducing the height between the surface of the melt and the outlet, thereby further reducing dust and particle generation.

When introducing elements of the present disclosure or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, “down”, “up”, etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A polycrystalline feed system for supplying chunk polycrystalline to a crucible containing a melt, the polycrystalline feed system comprising:
a feed tube having an outer sidewall and an outlet end;
a heat exchanger extending around, and spaced from, the outer sidewall of the feed tube for cooling the feed tube; and
a shield assembly connected to the feed tube, the shield assembly including a heat shield extending radially between the outer sidewall of the feed tube and the heat exchanger to shield at least a portion of the feed tube from the heat of the melt.

2. The polycrystalline feed system of claim 1, wherein the heat shield is positioned at the outlet end of the feed tube.

3. The polycrystalline feed system of claim 1, wherein the shield assembly further comprises a support ring positioned exterior to the outer sidewall of the feed tube and a tube support extending from the support ring to the heat shield, the tube support supporting the heat shield at the outlet end.

4. The polycrystalline feed system of claim 3, wherein the tube support includes a plurality of cable hangers circumferentially spaced about the heat shield.

5. The polycrystalline feed system of claim 1, wherein the feed tube is moveable between a retracted position and an extended position in which the feed tube supplies chunk polycrystalline to the crucible, the shield assembly being attached to the feed tube such that the heat shield moves with the feed tube between the retracted position and the extended position.

6. The polycrystalline feed system of claim 5, wherein the heat exchanger includes an inner surface defining a heat exchange chamber, the heat shield and the feed tube each being positioned within the heat exchange chamber when the feed tube is in the extended position.

7. The polycrystalline feed system of claim 6, wherein the heat shield is sized to define a radial gap between an outer surface of the heat shield and the inner surface of the heat exchanger, the radial gap extending circumferentially around the heat shield.

8. The polycrystalline feed system of claim 5, wherein the heat shield does not contact the heat exchanger.

9. The polycrystalline feed system of claim 5 further comprising a feeder connection flange positioned above the heat exchanger, wherein the heat shield is positioned within a notch of the feeder connection flange when the feed tube is in the retracted position.

10. The polycrystalline feed system of claim 1, wherein the heat shield defines a central opening, the central opening being sized to receive the feed tube.

11. An ingot puller for manufacturing a single crystal ingot, the ingot puller comprising:
a crucible for holding a crystal melt;
a crystal puller housing that defines a growth chamber for pulling the ingot from the melt, the crucible being positioned within the growth chamber; and
a polycrystalline feed system for supplying chunk polycrystalline to the crucible, the polycrystalline feed system comprising:
a feed tube having an outer sidewall and an outlet end;
a heat exchanger extending around, and spaced from, the outer sidewall of the feed tube for cooling the feed tube; and
a shield assembly connected to the feed tube, the shield assembly including a heat shield extending radially between the outer sidewall of the feed tube and the heat exchanger to shield at least a portion of the feed tube from the heat of the melt.

12. The ingot puller of claim 11 further comprising a reflector positioned within the growth chamber, the reflector defining a central passage therein, wherein the heat exchanger is positioned within the central passage.

13. The ingot puller of claim 11, wherein the heat shield is positioned at the outlet end of the feed tube.

14. The ingot puller of claim 11, wherein the shield assembly further comprises a support ring positioned exterior to the outer sidewall of the feed tube and a tube support extending from the support ring to the heat shield, the tube support supporting the heat shield at the outlet end.

15. The ingot puller of claim 14, wherein the tube support includes a plurality of cable hangers circumferentially spaced about the heat shield.

16. The ingot puller of claim 11, wherein the feed tube is moveable between a retracted position and an extended position in which the feed tube supplies chunk polycrystalline to the crucible, the shield assembly being attached to the feed tube such that the heat shield moves with the feed tube between the retracted position and the extended position.

17. The ingot puller of claim 16, wherein the heat exchanger includes an inner surface defining a heat exchange chamber, the heat shield and the feed tube each being positioned within the heat exchange chamber when the feed tube is in the extended position.

18. The ingot puller of claim 17, wherein the heat shield is sized to define a radial gap between an outer surface of the heat shield and the inner surface of the heat exchanger, the radial gap extending circumferentially around the heat shield.

19. The ingot puller of claim 16, wherein the heat shield does not contact the heat exchanger.

20. The ingot puller of claim 16 further comprising a feeder connection flange positioned above the heat exchanger, wherein the heat shield is positioned within a notch of the feeder connection flange when the feed tube is in the retracted position.
